(19) United States
(12) Patent Application Publication
(10) Pub. No.: US 2026/0026362 A1
(43) Pub. Date: Jan. 22, 2026

(54) FABRICATING METHOD OF PACKAGE SUBSTRATE

(71) Applicant: AaltoSemi Inc., Nanjing City (CN)

(72) Inventors: Yin-Ju CHEN, Nanjing City (CN); Min-Yao CHEN, Nanjing City (CN); Sung-Kun LIN, Nanjing City (CN); Andrew C. CHANG, Nanjing City (CN)

(73) Assignee: AaltoSemi Inc., Nanjing City (CN)

(21) Appl. No.: 19/266,947

(22) Filed: Jul. 11, 2025

(30) Foreign Application Priority Data
Jul. 17, 2024 (CN) 202410958725.5

(51) Int. Cl. H01L 21/48

(52) U.S. Cl. CPC H01L 21/4846

(57) ABSTRACT

Provided is a method of fabricating a package substrate, including sequentially forming each of first metal layers and each of second metal layers on two opposite surfaces of a board body; forming a circuit structure on each of the second metal layers, thereby forming a multi-layer board assembly; positioning each of the multi-layer board assemblies on each of opposite sides of a support member; using the second metal layer adjacent to the support member as a separation line to separate into a processing board member and two intermediate board members; positioning each of the intermediate board members on each of opposite sides of another support member; removing the board body and the first metal layers to obtain another processing board member; forming a wiring layer on each of the circuit structures of the processing board members; and removing the support members.

### CROSS-REFERENCE TO RELATED APPLICATIONS

This application claims the benefit of priority of China Patent Application No. 202410958725.5, filed on Jul. 17, 2024, the entire contents of which are incorporated herein by reference.

### BACKGROUND

### 1. Technical Field

The present disclosure relates to a semiconductor packaging process, and more particularly, to a package substrate and a method of fabricating the same for improved reliability.

### 2. Description of Related Art

With the booming development of the electronics industry, electronic products tend to be thin, light and small in form, and the functionality is developing towards the direction of high-performance, high-function and high-speed research and development. Therefore, in order to meet the demand for high integration and miniaturization of semiconductor devices, package substrates having high-density and fine-pitch circuits are often used in the packaging process.

FIG. 1A to FIG. 1D are schematic cross-sectional views showing a conventional fabricating method of a package substrate 1 according to the prior art.

As shown in FIG. 1A, a carrier 9 is provided. The opposite surfaces of the board body 90 of the carrier 9 have a first metal layer 91 as a thicker copper foil, and a second metal layer 92 as a thinner copper foil is formed on each of the first metal layers 91 to form a wiring layer 10 on each of the second metal layers 92.

As shown in FIG. 1B, a circuit structure 11 is formed on each of the second metal layer 92. The circuit structure 11 includes a dielectric layer 110 formed on the second metal layer 92 and the wiring layer 10, a circuit layer 111 formed on the dielectric layer 110, and a plurality of conductive blind vias 112 formed in the dielectric layer 110 to electrically connect the circuit layer 111 and the wiring layer 10.

As shown in FIG. 1C, another circuit structure 11 is formed on each of the circuit structures 11.

As shown in FIG. 1D, the carrier 9 is removed to form a plurality of coreless package substrates 1.

However, the conventional package substrate 1 is a coreless embedded circuit specification. Therefore, the package substrate 1 is relatively non-tough, weak, and tends to be prone to warping, bending or other deformations during the fabricating process, and it is difficult to meet the need for thinning since it is not suitable for use with an ultra-thin dielectric layer 110 during the fabricating process.

Therefore, there is an urgent need to solve and overcome the serious disadvantages of the above-mentioned prior art technology.

### SUMMARY

In view of the various shortcomings of the aforementioned conventional technologies, the present disclosure provides a method of fabricating a package substrate. In an aspect, the method comprises: providing a carrier having a board body, a first metal layer formed on each of two opposite surfaces of the board body and a second metal layer formed on each of the first metal layers; forming a first circuit structure on each of the second metal layers; forming a second circuit structure on each of the first circuit structures, thereby forming a multi-layer board assembly comprising the carrier, the first circuit structures and the second circuit structures; positioning each of the multi-layer board assemblies on each of two opposite sides of a first support member; using the second metal layers of the carrier adjacent to the first support member as a separation line to separate into a first processing board member having the first support member and two intermediate board members having the board body; positioning each of the intermediate board members on each of two opposite sides of a second support member; removing the board body and the first metal layers from each of two opposite sides of the second support member to obtain a second processing board member having the second support member; forming a wiring layer on each of the first circuit structures of the first processing board member and the second processing board member by each of the second metal layers; and removing the first support member and the second support member to obtain a plurality of packaging substrates.

In some embodiments, each of the first circuit structures comprises a first dielectric layer formed on each of the second metal layers, a first circuit layer formed on the first dielectric layer, and a plurality of first conductive blind vias formed in the first dielectric layer and electrically connecting the first circuit layer and the wiring layer. Further, each of the second circuit structures comprises a second dielectric layer formed on each of the first circuit structures, a second circuit layer formed on the second dielectric layer, and a plurality of second conductive blind vias formed in the second dielectric layer and electrically connecting the second circuit layer and the first circuit layer. For example, the first conductive blind vias and the second conductive blind vias are in a shape of a cone, the first conductive blind vias and the second conductive blind vias are stacked mutually in the same direction, and a tapered bottom of the first conductive blind vias matches a tapered top of the second conductive blind vias.

In some embodiments, the first processing board member and the second processing board member are of the same structure.

In some embodiments, the first support member and/or the second support member is a thermal release tape or a temporary removable board having adhesive properties. For example, each of the second circuit structures is provided with a solder resist layer, the multi-layer board assemblies are bonded to the first support member by the solder resist layer, and the intermediate board members are bonded to the second support member by the solder resist layer.

In some embodiments, each of the first circuit structures comprises a first dielectric layer formed on each of the second metal layers and a first circuit layer formed on the first dielectric layer, and when the wiring layer is formed, a plurality of first conductive blind vias are formed in the first dielectric layer, electrically connecting the first circuit layer and the wiring layer. Further, each of the second circuit structures comprises a second dielectric layer formed on each of the first circuit structures, a second circuit layer formed on the second dielectric layer, and a plurality of second conductive blind vias formed in the second dielectric layer and electrically connecting the second circuit layer and the first circuit layer. For example, the first conductive blind vias and the second conductive blind vias are in a shape of a cone and stacked inversely to each other, and a tapered top of the first conductive blind vias matches a tapered top of the second conductive blind vias.

In summary, in the fabricating method of the package substrate of the present disclosure, each of the multi-layer board assemblies is pressed onto each of two opposite sides of the first support member to improve the toughness of the multi-layer board assemblies during the fabricating process. Therefore, compared with the conventional technologies, the first circuit structures and second circuit structures of the present disclosure can effectively avoid the problems of warping, bending or other deformations during the fabricating process, and thus the ultra-thin dielectric layer can be used as the first dielectric layer and the second dielectric layer to meet the needs of thinning.

### BRIEF DESCRIPTION OF THE DRAWINGS

FIG. 1A to FIG. 1D are schematic cross-sectional views showing a conventional fabricating method of a package substrate according to the prior art.

FIG. 2A to FIG. 2H are schematic cross-sectional views showing an exemplary method of fabricating a package substrate according to an embodiment of the present disclosure.

FIG. 3A to FIG. 3D are schematic cross-sectional views showing an exemplary method of fabricating a package substrate according to an embodiment of the present disclosure.

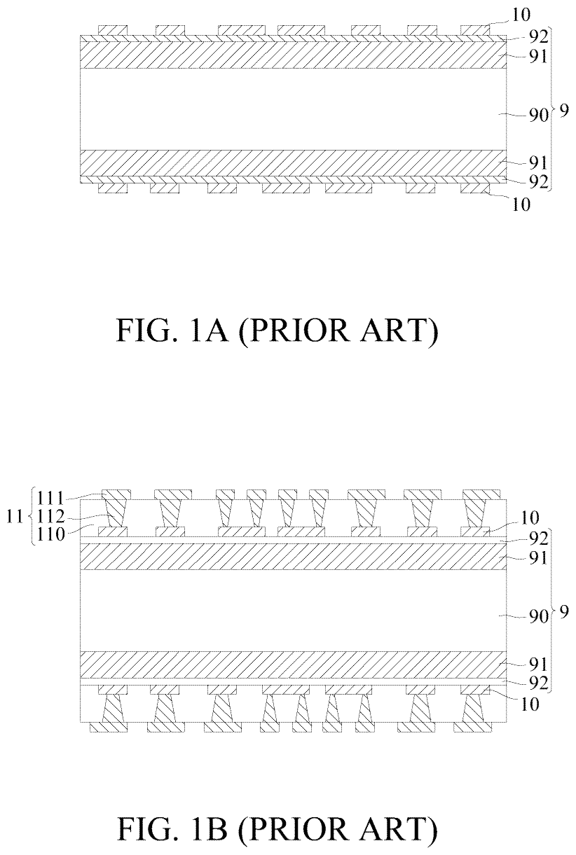

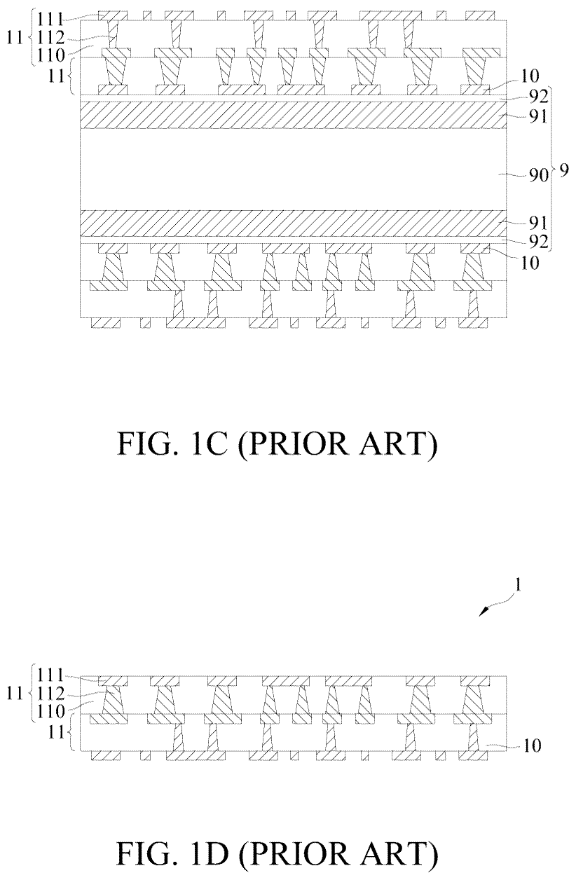

### DETAILED DESCRIPTION

Implementations of the present disclosure are illustrated below by embodiments. Those skilled in the art can easily understand other advantages and effects of the present disclosure from the content disclosed in this specification.

It should be understood that, the structures, ratios, sizes, and the like in the accompanying figures are used for illustrative purposes to facilitate the perusal and comprehension of the content disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical content disclosed in the present specification. Meanwhile, terms such as “on,” “first,” “second,” “a,” “one” and the like are merely used for clear explanation rather than limiting the practicable scope of the present disclosure, and thus, alterations or adjustments of the relative relationships thereof without essentially altering the technical content should still be considered in the practicable scope of the present disclosure.

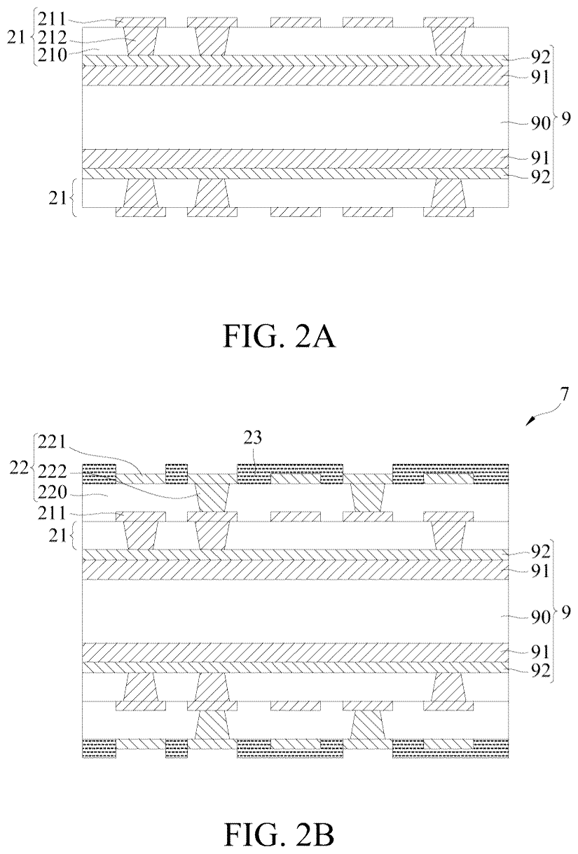

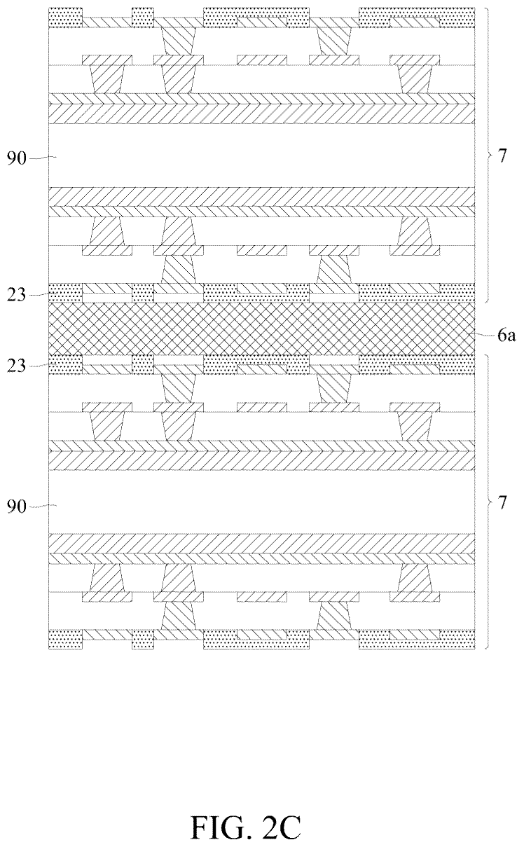

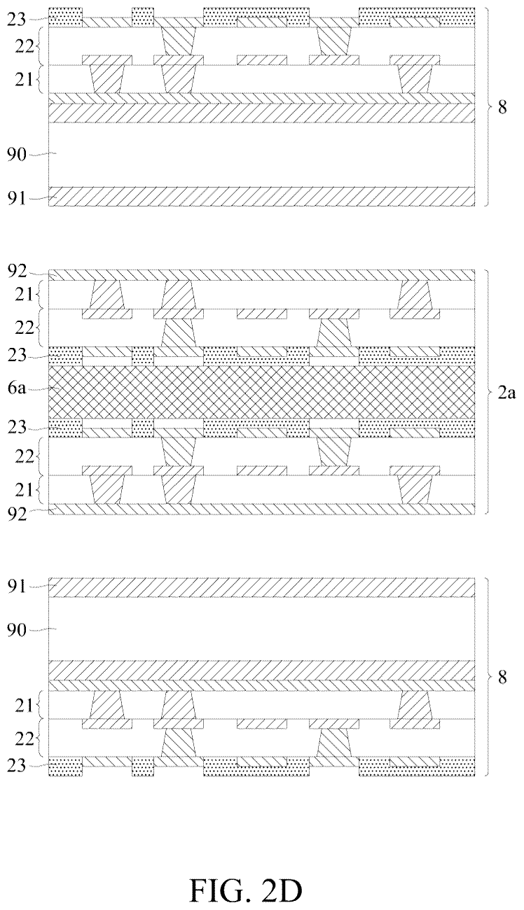

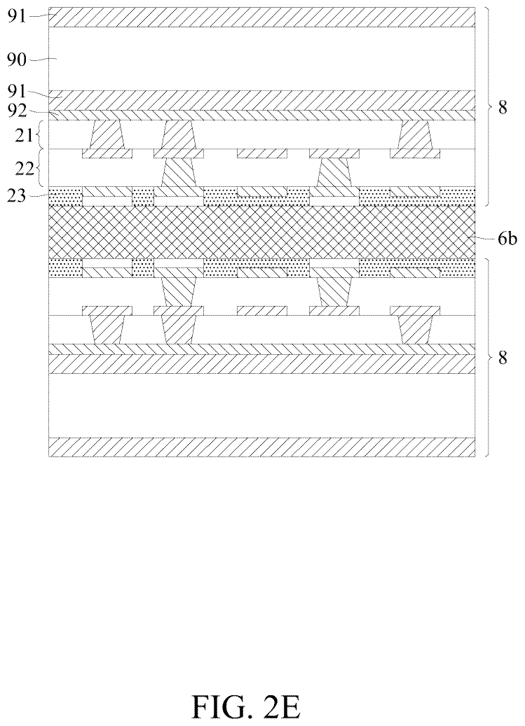

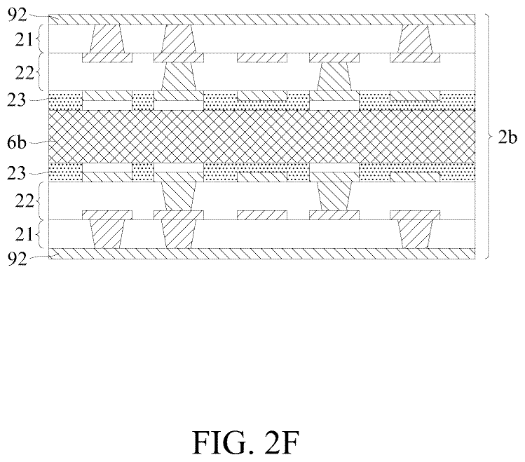

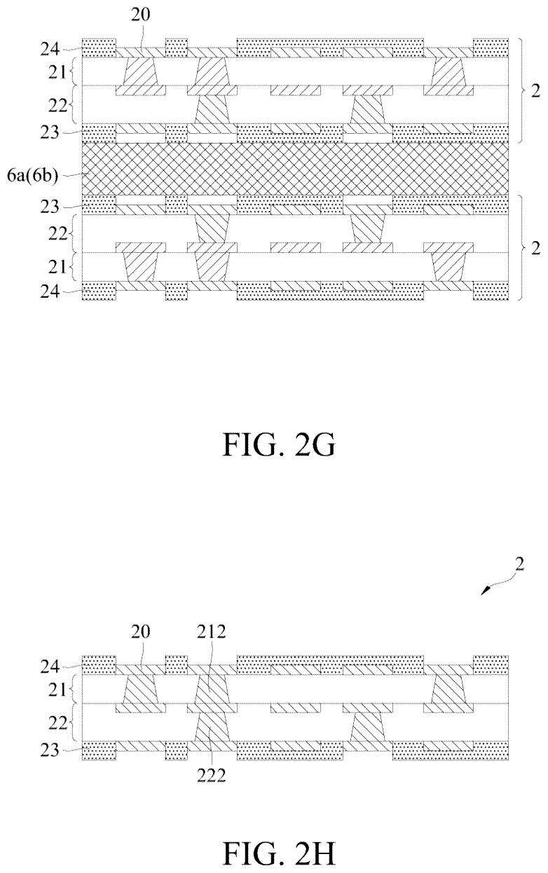

FIG. 2A to FIG. 2H are schematic cross-sectional views showing a method of fabricating a package substrate 2 according to a first exemplary embodiment of the present disclosure.

As shown in FIG. 2A, a carrier 9 is provided. The carrier 9 has a board body 90, each of first metal layers 91 formed on each of two opposite surfaces of the board body 90 and each of second metal layers 92 formed on each of the first metal layers 91. Each of first circuit structures 21 is formed on each of the second metal layers 92. Each of the first circuit structures 21 includes a first dielectric layer 210 formed on each second metal layer 92, a first circuit layer 211 formed on the first dielectric layer 210, and a plurality of first conductive blind vias 212 formed in the first dielectric layer 210 to electrically connect the first circuit layer 211 and each second metal layer 92.

In an exemplary embodiment, the first metal layer 91 is a thick copper layer, such as copper foil, with a thickness of about 18 micrometers (μm), such that the carrier 9 becomes a copper clad laminate (CCL). For example, each second metal layer 92 is a thin copper layer with a thickness of about 3 μm, which is formed on each first metal layer 91 by electroplating or deposition.

Moreover, the first dielectric layer 210 is a dielectric material, such as ajinomoto build-up film (ABF), polybenzoxazole (PBO), polyimide (PI), prepreg (PP) with glass fibers, or other dielectric materials.

Further, the first circuit layer 211 is fabricated by plating metal (e.g., copper) or other means by a build-up process. For example, a plurality of apertures is firstly formed in the first dielectric layer 210 by means of laser, and copper is subsequently plated on the first dielectric layer 210 and in the apertures to integrally form the first circuit layer 211 and the first conductive blind vias 212.

In addition, the first circuit layer 211 and the first conductive blind vias 212 adopt a circuit redistribution layer (RDL) specification, and the first conductive blind vias 212 are in the shape of a cone.

As shown in FIG. 2B, each of second circuit structures 22 is formed on each of the first circuit structures 21, and each of multi-layer board assemblies 7 is formed by means of the carrier 9, the first circuit structures 21 and the second circuit structures 22. The second circuit structure 22 includes a second dielectric layer 220 formed on the first dielectric layer 210 and the first circuit layer 211, a second circuit layer 221 formed on the second circuit layer 220, and a plurality of second conductive blind vias 222 formed in the second dielectric layer 220 to electrically connect the first circuit layer 211 and the second circuit layer 221.

In an exemplary embodiment, the second dielectric layer 220 is a dielectric material, such as ajinomoto build-up film (ABF), polybenzoxazole (PBO), polyimide (PI), prepreg (PP) with glass fibers, or other dielectric materials.

Moreover, the second circuit layer 221 is fabricated by plating metal (e.g., copper) or other means by means of a build-up process. For example, a plurality of apertures is firstly formed in the second dielectric layer 220 by means of laser, and copper is subsequently plated on the second dielectric layer 220 and in the apertures to integrally form the second circuit layer 221 and the second conductive blind vias 222.

Also, the second circuit layer 221 and the second conductive blind vias 222 adopt a circuit redistribution layer (RDL) specification, and the second conductive blind vias 222 are in the shape of a cone.

In addition, each solder resist layer 23, such as a green paint, is formed on each second circuit structure 22 (i.e., the outermost circuit structure), and a plurality of openings are formed in each of the solder resist layers 23 to expose each second circuit layer 221.

It should be appreciated that by utilizing the build-up process, the number of layers of each circuit structure can be designed according to the requirements to fabricate the desired number of layers of the circuit layer.

As shown in FIG. 2C, each of the multi-layer board assemblies 7 is provided on each of two opposite sides of a first support member 6a, and each multi-layer board assembly 7 is bonded to the first support member 6a by each solder resist layer 23.

In an exemplary embodiment, the first support member 6a is a thermal release tape or a temporary removable board having adhesive properties, such as a thermal release film in the form of a double-sided sticker.

As shown in FIG. 2D, the second metal layer 92 of the carrier 9 adjacent to the first support member 6a is used as a separation line for the board disassembling operation, so as to separate into a first processing board member 2a having the first support member 6a and two intermediate board members 8 having the board body 90, wherein there is a second metal layer 92 on two opposite sides of the first processing board member 2a.

As shown in FIG. 2E, each of the intermediate board members 8 is provided on opposite sides of a second support member 6b, and the intermediate board members 8 are bonded to the second support member 6b by the solder resist layer 23.

In an embodiment, the second support member 6b is a thermal release tape or a temporary removable board having adhesive properties, such as a thermal release film in the form of a double-sided sticker.

As shown in FIG. 2F, the board body 90 and the first metal layer 91 on each of two opposite sides of the second support member 6b are removed to obtain a second processing board member 2b having the second support member 6b such that the opposite sides of the second processing board member 2b have the second metal layer 92.

In an exemplary embodiment, the first processing board member 2a (as shown in FIG. 2D) and the second processing board member 2b are of the same structure.

As shown in FIG. 2G, a patterned wiring process is carried out on the first processing board member 2a and the second processing board member 2b to form a wiring layer 20 on the first circuit structure 21 by means of the second metal layer 92 such that the first conductive blind vias 212 electrically connects the wiring layer 20 and the first circuit layer 211.

In an embodiment, the wiring layer 20 adopts a circuit redistribution layer (RDL) specification.

In addition, another solder resist layer 24, such as a green paint, is formed on the first circuit structure 21, and a plurality of openings are formed in each solder resist layer 24 to expose the wiring layer 20 such that a plurality of solder balls (not shown) may be bonded to the exposed surfaces of the wiring layer 20 and/or the second circuit layer 221 in the subsequent fabricating process for external connection of an electronic device (e.g., semiconductor chips, passive components, silicon intermediate boards, circuit boards, or other components).

As shown in FIG. 2H, the first support member 6a and the second support member 6b are removed by heating to obtain a plurality of coreless package substrates 2 (e.g., four coreless package substrates).

In an exemplary embodiment, the first conductive blind vias 212 and the second conductive blind vias 222 of the package substrate 2 are stacked mutually in the same direction such that the tapered bottom of each of the first conductive blind vias 212 matches the tapered top of each of the second conductive blind vias 222 in the shape of a tower.

Therefore, in an exemplary embodiment, the fabricating method of the present disclosure is mainly to improve the toughness of the multi-layer board assembly during the fabricating process by means of pressing the multi-layer board assembly 7 onto the opposite sides of the first support member 6a. Accordingly, compared with the conventional technology, the first circuit structure 21 and the second circuit structure 22 can avoid warping, bending or other deformations during the fabricating process. Hence, an ultra-thin dielectric layer can be used as the first dielectric layer 210 and the second dielectric layer 220 to meet the demand for thinning.

Moreover, by bonding the extremely thin multi-layer board assembly 7 onto the opposite surfaces of the first support member 6a for processing, in order to increase the structural thickness desired for the fabricating process, the processability of the ultra-thin multi-layer board assembly 7 is not limited by the performance of the equipment so as to achieve the capability of the equipment of the smallest board thickness. As such, in the method of fabricating the packaging substrate 2, any ultra-thin thickness of multi-layer board assembly 7 (e.g., the thickness of the multi-layer board assembly 7 may be 0.01, 0.015, 0.02, 0.03, 0.04 mm, etc.) can be processed in the above manner by using the conventional processing equipment, thereby eliminating the need to use special equipment and thus significantly reducing processing costs.

Furthermore, by bonding two intermediate board members 8 having the board body 90 on opposite sides of the second support member 6b, and then removing the board body 90 and the first metal layer 91 from opposite sides of the second support member 6b, another processing board member (i.e., the second processing board member 2b having the second support member 6b) is obtained. Thus, the fabricating method of the package substrate 2 can carry out the patterned wiring process for two sets of processing board members (the first processing board member 2a and the second processing board member 2b) in order to obtain more package substrates 2, thereby increasing production.

In addition, the first support member 6a and the second support member 6b are removed by heating to weaken the adhesion between each of the support members and the solder resist layer 23 such that damage to the surface of the package substrate 2 can be avoided when the first support member 6a and the second support member 6b are removed.

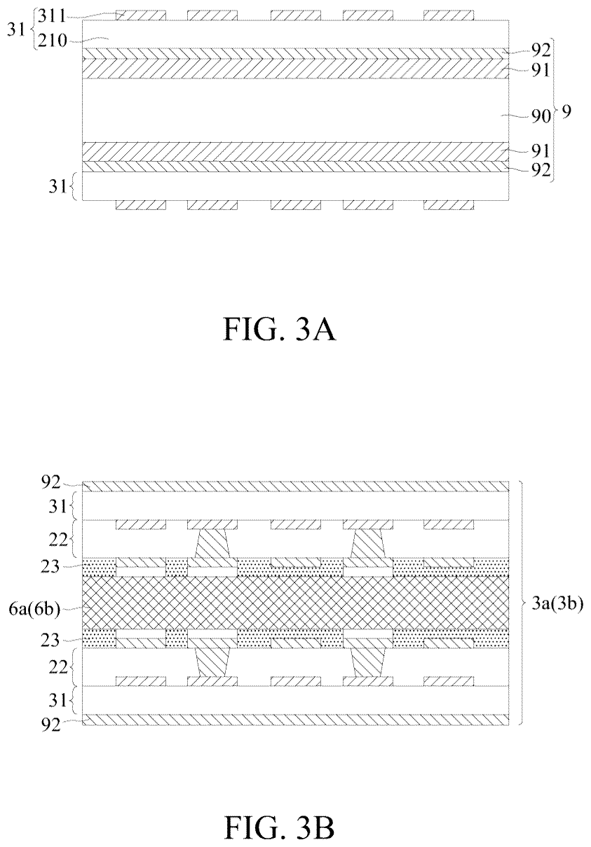

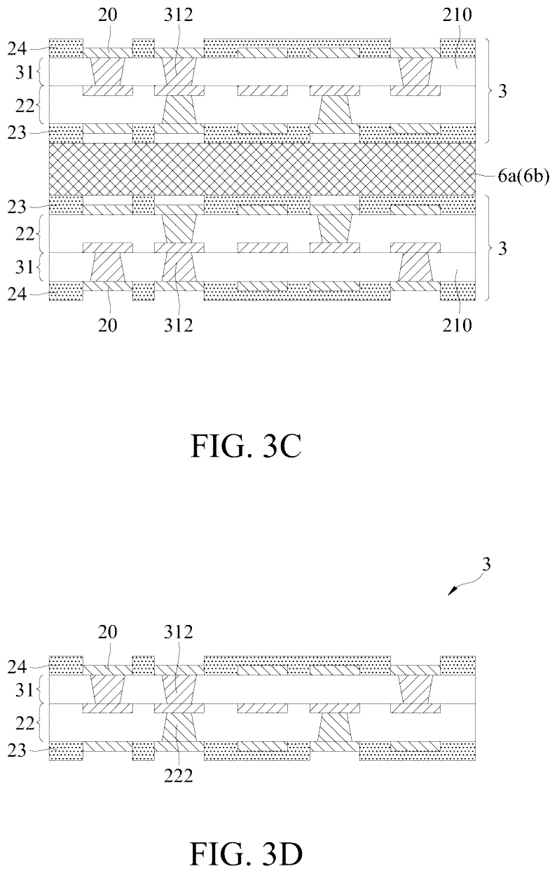

FIG. 3A to FIG. 3D are schematic cross-sectional views showing a method of fabricating a package substrate 3 according to a second embodiment of the present disclosure. The difference between this embodiment and the first embodiment lies in the fabricating sequence of the first conductive blind vias 312, while the other fabricating processes are more or less the same. Hence, the similarities will not be repeated hereinafter.

As shown in FIG. 3A, the first conductive blind vias 212 are not formed when the first circuit structure 31 is fabricated in the fabricating process of FIG. 2A. Accordingly, the first circuit structure 31 includes a first dielectric layer 210 formed on the second metal layer 92 and a first circuit layer 211 formed on the first dielectric layer 210, but does not have the first conductive blind vias.

As shown in FIG. 3B, the fabricating processes of FIG. 2B to FIG. 2F are used to obtain a first processing board member 3a having the first support member 6a and a second processing board member 3b having the second support member 6b.

As shown in FIG. 3C, a patterned wiring process is carried out on the first processing board member 3a and the second processing board member 3b to form a wiring layer 20 on the first circuit structure 31 by means of the second metal layer 92, and when the wiring layer is formed, a plurality of first conductive blind vias 312 are formed in the first dielectric layer 210 of the first circuit structure 31 to electrically connect the wiring layer 20 and the first circuit layer 211.

In an exemplary embodiment, the wiring layer 20 is fabricated by plating metal (e.g., copper) or other means using a build-up process. For example, a plurality of apertures is firstly formed in the first dielectric layer 210 by means of laser, and copper is subsequently plated on the first dielectric layer 210 and in the apertures to integrally form the wiring layer 20 and the first conductive blind vias 312.

Moreover, the wiring layer 20 and the first conductive blind vias 312 adopt a circuit redistribution layer (RDL) specification, and the first conductive blind vias 312 are in the shape of a cone.

In addition, another solder resist layer 24, such as a green paint, is formed on the first circuit structure 31, and a plurality of openings are formed in each solder resist layer 24 to expose the wiring layer 20 such that a plural of solder balls (not shown) may be bonded to the exposed surface of the wiring layer 20 and/or the second circuit layer 221 in the subsequent fabricating process for external connection of an electronic device (e.g., semiconductor chips, passive components, silicon intermediate boards, circuit boards, or other components).

As shown in FIG. 3D, the first support member 6a and the second support member 6b are removed to obtain a plurality of coreless package substrates 3.

In an embodiment, the first conductive blind vias 312 and the second conductive blind vias 222 of the packaging substrate 3 are stacked inversely to each other such that the tapered top of each of the first conductive blind vias 312 matches the tapered top of each of the second conductive blind vias 222 in a gourd-like shape or a X shape.

Therefore, the fabricating method of the package substrate of the present disclosure is to improve the toughness of the multi-layer board assembly during the fabricating process by means of pressing the multi-layer board assembly onto two opposite sides of the first support member. Accordingly, the first circuit structure and the second circuit structure of the present disclosure can avoid warping, bending, or other deformation during the fabricating process. Hence, an ultra-thin dielectric layer can be used as the first dielectric layer and the second dielectric layer in order to meet the demand for thinning.

Moreover, by bonding the extremely thin multi-layer board assembly onto the opposite surfaces of the first support member for processing, in order to increase the structural thickness desired for the fabricating process, the processability of the ultra-thin multi-layer board assembly is not limited by the performance of the equipment so as to achieve the capability of the equipment of the smallest board thickness. As such, in the fabricating method of the present disclosure, any ultra-thin thickness of multi-layer plate assemblies can be processed in the above manner by using the conventional processing equipment, thereby eliminating the need to use special equipment and thus significantly reducing processing costs.

Further, by bonding two intermediate board members having the board body on opposite sides of the second support member, and then removing the board body and the first metal layer from opposite sides of the second support member, another processing board member is obtained. Thus, the fabricating method of the package substrate can carry out the patterned wiring process for two sets of processing board members in order to obtain more package substrates, thereby increasing production.

In addition, the support members are removed by heating to weakens the adhesion between each of the support members and the solder resist layer such that damage to the surface of the package substrate can be avoided when the support members are removed.

The above embodiments are provided for illustrating the principles of the present disclosure and its technical effect and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. A method of fabricating a package substrate, the method comprising:
providing a carrier having a board body, a first metal layer formed on each of two opposite surfaces of the board body and a second metal layer formed on each of the first metal layers;
forming a first circuit structure on each of the second metal layers;
forming a second circuit structure on each of the first circuit structures, thereby forming a multi-layer board assembly comprising the carrier, the first circuit structures and the second circuit structures;
positioning each of the multi-layer board assemblies on each of two opposite sides of a first support member;
using the second metal layers of the carrier adjacent to the first support member as a separation line to separate into a first processing board member having the first support member and two intermediate board members having the board body;
positioning each of the intermediate board members on each of two opposite sides of a second support member;
removing the board body and the first metal layers from each of two opposite sides of the second support member to obtain a second processing board member having the second support member;
forming a wiring layer on each of the first circuit structures of the first processing board member and the second processing board member by each of the second metal layers; and
removing the first support member and the second support member to obtain a plurality of packaging substrates.

2. The method of claim 1, wherein each of the first circuit structures comprises a first dielectric layer formed on each of the second metal layers, a first circuit layer formed on the first dielectric layer, and a plurality of first conductive blind vias formed in the first dielectric layer and electrically connecting the first circuit layer and the wiring layer.

3. The method of claim 2, wherein each of the second circuit structures comprises a second dielectric layer formed on each of the first circuit structures, a second circuit layer formed on the second dielectric layer, and a plurality of second conductive blind vias formed in the second dielectric layer and electrically connecting the second circuit layer and the first circuit layer.

4. The method of claim 3, wherein the first conductive blind vias and the second conductive blind vias are in a shape of a cone, the first conductive blind vias and the second conductive blind vias are stacked mutually in the same direction, and a tapered bottom of the first conductive blind vias matches a tapered top of the second conductive blind vias.

5. The method of claim 1, wherein the first processing board member and the second processing board member are of the same structure.

6. The method of claim 1, wherein the first support member and/or the second support member is a thermal release tape or a temporary removable board having adhesive properties.

7. The method of claim 6, wherein each of the second circuit structures is provided with a solder resist layer, the multi-layer board assemblies are bonded to the first support member by the solder resist layer, and the intermediate board members are bonded to the second support member by the solder resist layer.

8. The method of claim 1, wherein each of the first circuit structures comprises a first dielectric layer formed on each of the second metal layers and a first circuit layer formed on the first dielectric layer, and when the wiring layer is formed, a plurality of first conductive blind vias are formed in the first dielectric layer, electrically connecting the first circuit layer and the wiring layer.

9. The method of claim 8, wherein each of the second circuit structures comprises a second dielectric layer formed on each of the first circuit structures, a second circuit layer formed on the second dielectric layer, and a plurality of second conductive blind vias formed in the second dielectric layer, electrically connecting the second circuit layer and the first circuit layer.

10. The method of claim 9, wherein the first conductive blind vias and the second conductive blind vias are in a shape of a cone and stacked inversely to each other, and a tapered top of the first conductive blind vias matches a tapered top of the second conductive blind vias.
